(19) United States
(12) Patent Application Publication
(10) Pub. No.: US 2024/0402315 A1
(43) Pub. Date: Dec. 5, 2024

(54) OPTICAL DEVICE FOR PROXIMITY SENSING OR ABSOLUTE DISTANCE MEASUREMENTS

(71) Applicant: AMS INTERNATIONAL AG, Jona (CH)

(72) Inventors: Laurent NEVOU, Wadenswil (CH); Ferran SUAREZ, Rueschlikon (CH); Daniel NAJER, Rotkreuz (CH); Ioannis PAPADOPOULOS, Eindhoven (NL)

(21) Appl. No.: 18/691,507

(22) PCT Filed: Nov. 22, 2022
(86) PCT No.: PCT/EP2022/082865

§ 371 Date: Mar. 13, 2024

(30) Foreign Application Priority Data
Nov. 23, 2021 (EP) 21386072.9

(51) Int. Cl. G01S 7/4912; G01S 7/481; G01S 7/4915; G01S 7/497; G01S 17/32

(52) U.S. Cl. CPC G01S 7/4916; G01S 7/4814; G01S 7/4915; G01S 7/497; G01S 17/32

(57) ABSTRACT

An optical device for proximity sensing includes a tunable laser source for emitting laser light. The tunable laser source includes a vertical cavity surface emitting laser, VCSEL. The VCSEL includes a microelectromechanical system, MEMS, for tuning the VCSEL by changing a length of a laser cavity of the VCSEL and includes a receiver configured to receive laser light emitted by the tunable laser source and reflected from an object.

### RELATED APPLICATION(S)

This application is a US National Stage Application of International Application PCT/EP2022/082865, filed on 22 Nov. 2022, and claims priority under 35 U.S.C. § 119 (a) and 35 U.S.C. § 365 (b) from European Application EP 21386072.9, filed on 23 Nov. 2021, the contents of which are incorporated herein by reference in their entirety.

### FIELD

The present disclosure relates to an optical device, in particular for proximity sensing and/or distance measurements.

### BACKGROUND

Proximity sensing and distance measurements are used in various technical fields such as in the mobile device industry (e.g. for gesture recognition) and in the automotive industry (e.g. for autonomous vehicles).

Laser based sensors can use interference for long distance measurements (typically greater than a couple of meters). The sensor works by emitting laser light and receiving reflections from a target. The reflections interfere with emitted light (e.g. a reference beam) to provide a measureable signal. Self-mixing interferometry (SMI), wherein the reflected light is received back in the emitting laser cavity can also be used.

To measure short distances (e.g. below one meter) the accuracy of interference based laser sensor is insufficient for many applications, and other devices such acoustic sensors may be preferred.

### SUMMARY

Various embodiments of the present disclosure relate to an optical device for distance measurements, which can be used to measure short distances (e.g. below 1 meter).

According to a first aspect of the present disclosure there is provided an optical device for proximity sensing comprising a tunable laser source for emitting laser light, wherein the tunable laser source comprises a vertical cavity surface emitting laser, VCSEL, comprising a microelectromechanical system, MEMS, for tuning the VCSEL by changing a length of a laser cavity of the VCSEL, and a receiver configured to receive laser light emitted by the tunable laser source and reflected from an object.

The optical device may be a proximity sensor, a contact sensor, an angular sensor or a loudspeaker feedback sensor for example, and may be integrated in smartphones, headphones and wearables such as smart watches and smart glasses etc.

The optical device can be configured to detect the presence of and/or measure a distance to the object when the distance is less than 50 cm, or less than 10 mm (e.g. depending on the application). For example, the optical device may be configured to operate below these distances with an accuracy of 1% or 2%.

The VCSEL can also be used as the receiver, and the optical device is then configured to measure the received laser light using self-mixing interferometry, SMI. The device may comprise a monitoring unit for monitoring the power input to the VCSEL laser (e.g. measuring a voltage or current input) to measure the received laser light. Alternatively, the optical device may comprise an optical sensor (e.g. comprising a photodiode) configured to measure a part of the laser light emitted by the VCSEL to measure the received laser light. In both cases, fringe counting or Fast Fourier Transform (FFT) is used for the measurement. Fringe counting directly measures the number of fringes in an SMI signal trace during a wavelength ramp (e.g. by differentiation of the signal and counting of zero crossings), while FFT computes the frequencies associated with the number of fringes per time interval in the SMI signal.

The optical device may be configured to measure the received laser light using frequency modulated continuous wave (FMCW) technology. For example, the optical device may be arranged for Michelson type measurements.

The MEMS can be configured to change the length of the laser cavity by up to at least 20 nm or by up to at least 30 nm. This relatively great distance enables accurate short distance measurements. Typically, the MEMS is configured to deflect a reflecting surface (e.g. a Bragg reflector) at one end of the VCSEL. The VCSEL can be configured to emit laser light having a wavelength in the range of 350 nm to 1600 nm.

According to a second aspect of the present disclosure there is provided a method of measuring a distance using an optical device according to the first aspect. The method typically comprises fringe counting or FFT. The method may further include tuning the tunable laser source while keeping the output power of the tunable laser source constant.

### BRIEF DESCRIPTION OF THE DRAWINGS

In the drawings, like reference characters generally refer to the same parts throughout the different views. The drawings are not necessarily to scale, emphasis instead generally being placed upon illustrating the principles disclosed herein. These and other aspects of the present disclosure will now be described, by way of example only, with reference to the accompanying drawings, wherein:

FIG. 1 shows a schematic diagram of an optical device according to at least one embodiment of the present disclosure;

FIG. 2A shows a schematic diagram of a VCSEL with a MEMS tunable laser cavity;

FIG. 2B shows the VCSEL when the MEMS is activated to deflect the top mirror of the VCSEL;

FIG. 3 shows graphs illustrating the number of peaks in the interference signal as a function of the distance L and laser tuning Δλ;

FIG. 4 shows the accuracy for different numbers of interference peaks (fringes N) as a function of distance L and tuning Δλ; and

FIG. 5 illustrates the change in wavelength as the length of the laser cavity of a VCSEL is changed.

### DETAILED DESCRIPTION

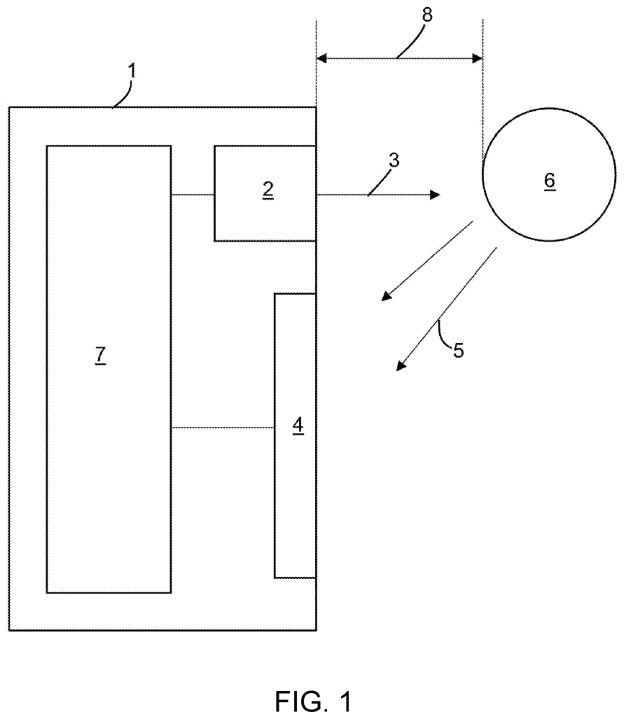

FIG. 1 shows a schematic diagram of an optical device 1 such as a proximity sensor for small distances (e.g. <1 m). The optical device 1 comprises a tunable laser source 2 for emitting laser light 3, a receiver 4 for receiving laser light 5 emitted by the source and reflected from an object 6. The device 1 further comprises a processing unit 7, which communicates with the laser source 2 and the receiver 4 and may, for example, provide trigger signals. The distance 8 between the device 1 and the object 6 may be less than a meter (e.g. as small as <10 mm). To improve the accuracy of the device 1 sufficiently for such short distances, the frequency range of the tunable laser source 2 has to be extended compared to conventional laser based proximity sensors. Hence, the tunable laser source 2 comprises means for changing the wavelength of up to at least 30 nm. The tunable laser source 2 comprises a vertical cavity surface emitting laser (VCSEL), which comprises a microelectromechanical system (MEMS) for tuning the VCSEL by changing the length of the laser cavity. For example, the MEMS may be connected to a variable voltage source and the change in length of the laser cavity may depend substantially linearly on the voltage applied to the MEMS by the voltage source.

In other embodiments, the laser source 2 is also used as the receiver, using so called self-mixing interferometry (SMI). In SMI, in general, light is emitted from a resonant light source (having an optical resonator in which the light circulates), typically a laser, and a portion of the light is fed back into the resonator, e.g. after the light has been reflected from an object. The feed-back light interacts with the light in the resonator, and introduces a disturbance in the light source by interference. This effect can be sensed and can be related to the interaction with the object, such as to a distance to the object or a velocity of the object (relative to the light source/resonator exit mirror).

SMI sensing can be accomplished in different ways:
a) optically: the emitted light intensity can be monitored, e.g., using a photodiode. For example:
   a1) a beam splitter can be positioned close to the exit mirror to let pass most of the light exiting the exit mirror and reflect a small portion thereof to a photo detector; or
   a2) also the other mirror of the resonator can be made partially transmissive (e.g., 99.5% instead of 100% reflective), and the photo detector is positioned close that mirror. This can be a more compact solution than a1).
b) electrically: a feed signal (driving signal) for the light source is monitored, e.g.,
   b1) the light source is driven with a current, and the change in voltage is determined; or
   b2) the light source is driven with a voltage, and the change in current is determined. The electrical signal may be noisier than the optically obtained signal.

In order to do absolute distance measurements with SMI, the laser must be single frequency, which results in a single mode longitudinal and transverse laser. The laser source must also be tunable in order to get good accuracy. In conventional SMI based distance sensors, the wavelength tuning happens by temperature change of the optical index (0.07 nm/K in GaAs=>Δλ˜3.5 nm/50K). Current tuning provides ˜0.6 nm/mA, but single mode VCSEL have a current dynamic of ˜2 mA, which gives Δλ˜1.2 nm/2 mA.

Embodiments described herein provide a VCSEL with a tunable MEMS cavity in order to extend the wavelength tunability of the laser to Δλ˜30 nm for SMI absolute distance measurements. Embodiments may be particularly suitable for short absolute distance measurements using SMI.

Embodiments described herein are able to tune and keep the output power constant. By contrast, using standard current ramp, the output power is strongly affected, which can make post processing of data more difficult.

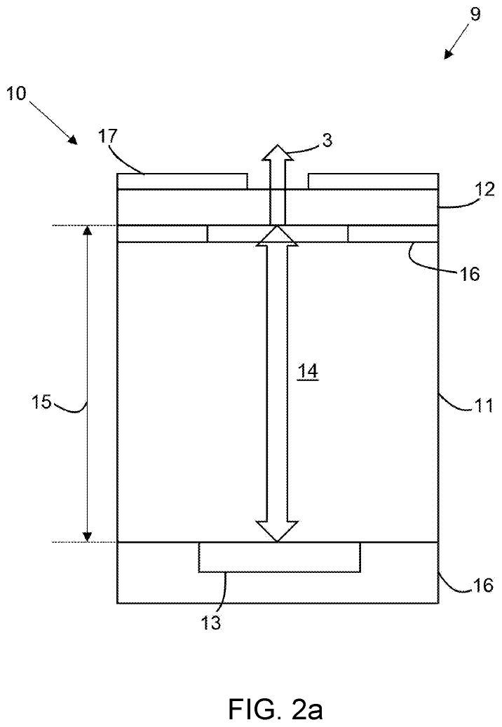

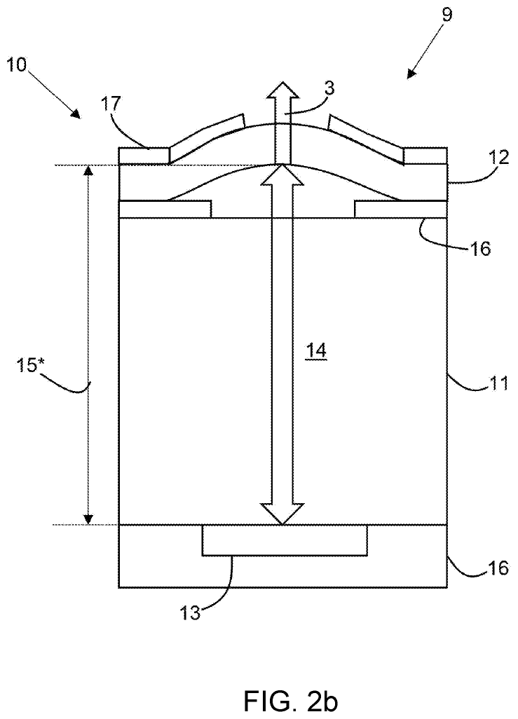

FIG. 2A shows a schematic diagram of a VCSEL 9 with an integrated MEMS 10 for tuning the VCSEL 9. The VCSEL 9 may be part of the tunable laser source of FIG. 1. The VCSEL 9 comprises a semiconductor substrate 11 between two mirrors 12 and 13, which define the laser cavity 14 between them. The length 15 of the laser cavity 14 is defined by the distance between the mirrors 12 and 13. Electrodes 16 connected to the semiconductor substrate 11 allow current to be injected in order to power the laser. The top mirror 12 is not completely reflective in order to allow some light 3 to escape and thereby provide the output of the laser. The top mirror 12 is mounted on the MEMS 10 and is configured to be displaced by the MEMS 10 so that the length 15 of the laser cavity 14 is increased. MEMS electrodes 17 are connected to the mirror 12 in order to actuate the mirror 12 by applying a voltage.

FIG. 2B shows a schematic diagram of the VCSEL 9 when the MEMS 10 is used to displace the top mirror 12, which thereby extends the length 15* of the laser cavity 14. The increased length 15* of the laser cavity 14 increases the wavelength of the laser light generated and the output 3. The greater the displacement of the mirror 12 the greater the change in wavelength.

The accuracy of the optical device is determined by the number of interference fringes N. At large distances, N is large while at small distances N can be very small or even null. The amount of fringes N is proportional to the product L*Δλ

$$N = 2 * Δλ * L / {λ}^{2}$$

Therefore, short distance lead to small N value

At low distances (e.g. L<1 cm), the tuning capability Δλ must be extend in order to compensate the small L and get a good accuracy on the absolute distance measurements.

Embodiments of the present disclosure are based on the insight that it can be valuable to be able to determine absolute distances which are small, such as below 20 mm or even below 10 mm and that it can be possible to do so using the “fringe-counting” or FFT type of absolute distance measurements.

Further, the number of interference fringes occurring in case of conventional wavelength-tuning methods (varying temperature/varying driving signal) is very low in case of small distances. The small number of countable fringes can result in an unacceptably low resolution.

The number N of fringes occurring in such measurements, when the averaged laser wavelength λ is varied by Δλ, can be calculated as

$$N = 2 * L * Δλ / {λ}^{2}$$

In order to achieve a better resolution at a given distance L, the number of fringes N should be increased, which can be accomplished (cf. the formula above) by
decreasing the laser wavelength λ; and/or
increasing the laser wavelength tuning range Δλ.

Using a MEMS-tunable laser can enable measurements at short distances (such as below 10 mm) while still having a reasonable resolution.

For example, one can define “short distance” at an arbitrary (averaged) laser wavelength λ under the assumption that an accuracy of at least 2% is required (corresponding to N=50). Distances in that range are not accessible to conventional “fringe counting” SMI absolute distance measurement setups (at 2% accuracy).

When using a MEMS-tunable VCSEL that is tunable over 20 nm or 30 nm or even more, such short distances are made available to the fringe-counting type of SMI-based measurements. For example, for a tunability of Δλ=20 nm, measurements of 2% accuracy can be accomplished still at distances as small as L=2.5 mm.

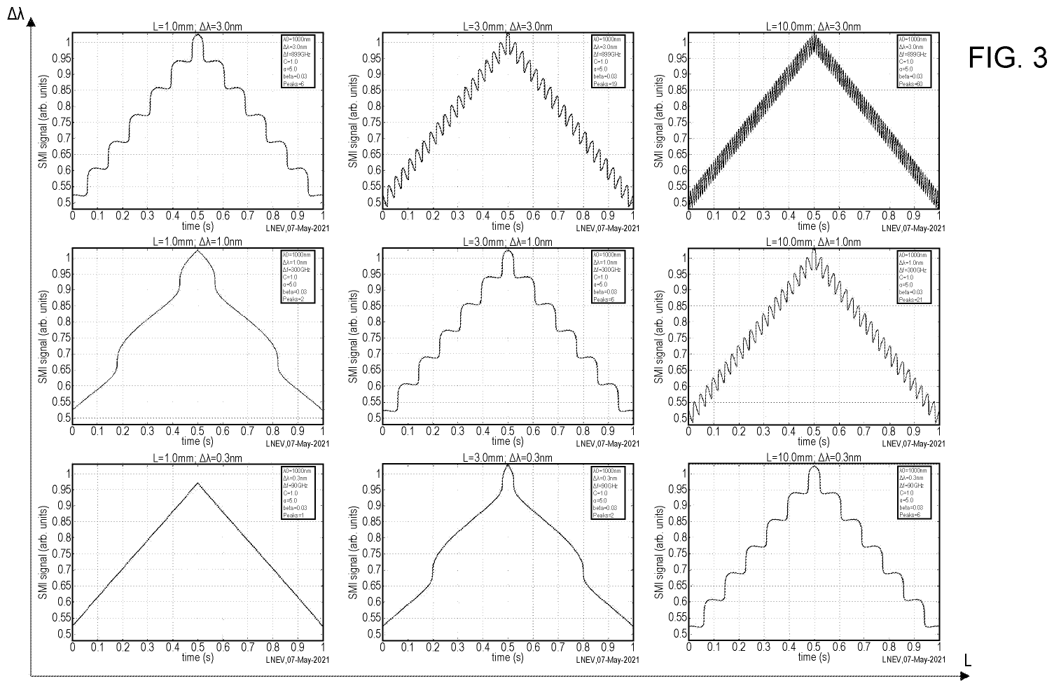

FIG. 3 illustrates how the number of fringes N changes with L and Δλ for a nominal wavelength (λ₀) of 1000 nm. In the bottom left graph, there is only one peak in the SMI signal, whereas in the top right graph there are 60 peaks in the SMI signal.

The accuracy also increases when the wavelength is shorter:
For λ=1000 nm; Δλ=1 nm and L=10 mm=>N=20
For λ=700 nm; Δλ=1 nm and L=10 mm=>N=40
For λ=450 nm; Δλ=1 nm and L=10 mm=>N=99

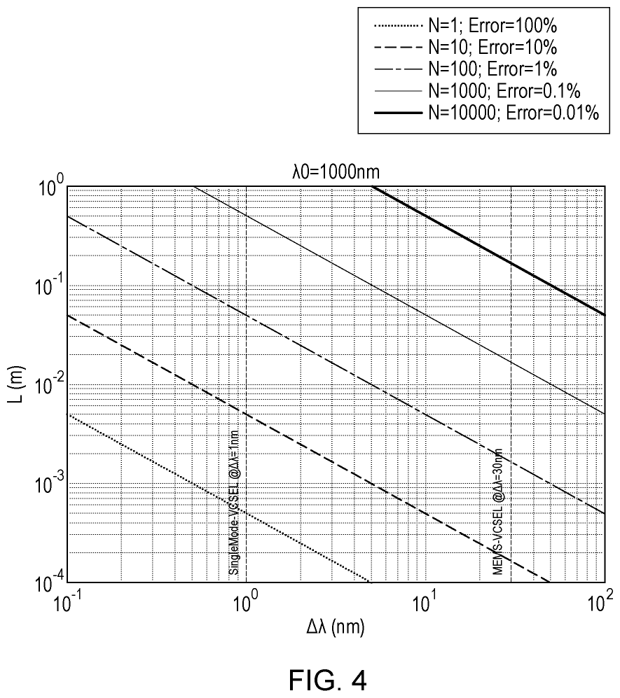

FIG. 4 shows a graph illustrating the accuracy of an SMI absolute distance sensor as a function of L and Δλ. Embodiments of the MEMS-VCSEL have ˜30 times larger tunability than a single mode VCSEL, and, as a result, the accuracy is ˜30 times higher. For λ=1000 nm, to get an accuracy >1%:
L>1.7 mm with MEMS-VCSEL (Δλ˜30 nm)
L>50 mm with single mode laser (Δλ˜1 nm)

Furthermore, a MEMS-VCSEL can have very fast tuning ˜MHz, and the tunability can be better controlled with MEMS than with conventional current ramp.

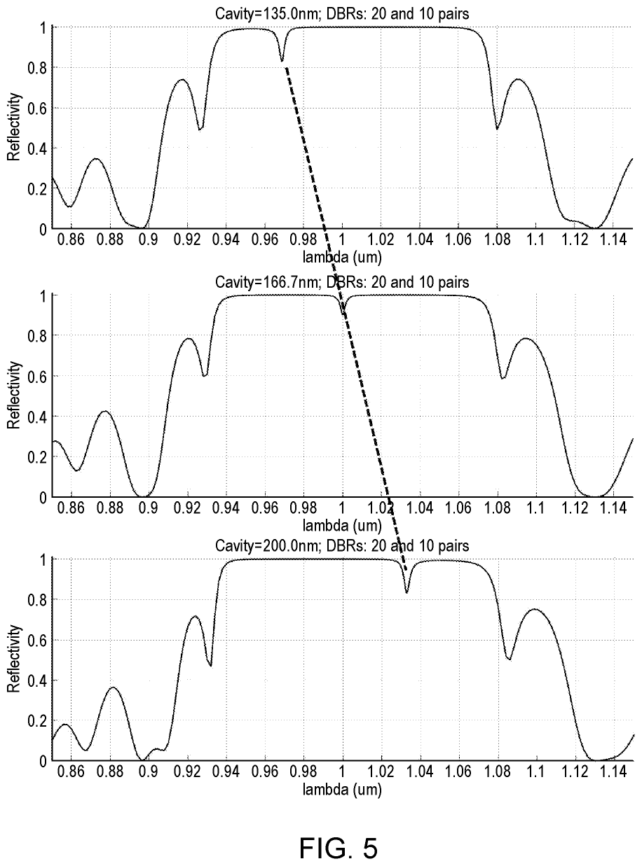

FIG. 5 illustrates how the wavelength of a VCSEL laser changes as the length of the laser cavity changes from 135 nm (top graph) to 200 nm (bottom graph).

Although specific embodiments have been described above, the claims are not limited to those embodiments. Each feature disclosed may be incorporated in any of the described embodiments, alone or in an appropriate combination with other features disclosed herein.

Reference Numerals

| | |
|---|---|
| 1 | Optical device |
| 2 | Tunable laser source |
| 3 | Emitted laser light |
| 4 | Receiver |
| 5 | Reflected laser light |
| 6 | Object |
| 7 | Processing unit |
| 8 | Distance |
| 9 | VCSEL |
| 10 | MEMS |
| 11 | Semiconductor substrate |
| 12 | Top mirror |
| 13 | Bottom mirror |
| 14 | Laser cavity |
| 15 | Length of laser cavity |
| 16 | Bottom electrode |
| 17 | Top electrode |

1. An optical device for proximity sensing comprising:
a tunable laser source for emitting laser light, wherein the tunable laser source comprises a vertical cavity surface emitting laser, VCSEL, comprising a microelectromechanical system, MEMS, for wavelength tuning the VCSEL by changing a length of a laser cavity of the VCSEL; and
a receiver configured to receive laser light emitted by the tunable laser source and reflected from an object;
wherein the optical device is configured to keep an output power of the tunable laser source constant while tuning the VCSEL.

2. The optical device according to claim 1, wherein the optical device is configured to detect the presence of and/or measure a distance to the object when the distance is less than 50 cm.

3. The optical device according to claim 1, wherein the optical device is configured to detect the presence of and/or measure a distance to the object when the distance is less than 10 mm.

4. The optical device according to claim 1, wherein the receiver is the VCSEL, and the optical device is configured to measure the received laser light using self-mixing interferometry, SMI.

5. The optical device according to claim 4, further comprising a monitoring unit for monitoring the power input to the VCSEL to measure the received laser light.

6. The optical device according to claim 4, further comprising an optical sensor configured to measure a part of the laser light emitted by the VCSEL to measure the received laser light.

7. The optical device according to claim 1, wherein the optical device is configured to measure the received laser light using frequency modulated continuous wave (FMCW) technology.

8. The optical device according to claim 1, wherein the MEMS is configured to change the length of the laser cavity by up to at least 30 nm.

9. The optical device according to claim 1, wherein the MEMS is configured to deflect a reflecting surface at one end of the VCSEL.

10. The optical device according to claim 9, wherein the reflecting surface is a Bragg reflector.

11. The optical device according to claim 1, wherein the VCSEL is configured to emit laser light having a wavelength in the range of 350 nm to 1600 nm.

12. A method of measuring a distance using an optical device according to claim 1.

13. The method according to claim 12, wherein the method comprises fringe counting or performing a Fast Fourier Transform, FFT.

14. The method according to claim 12, wherein the method comprises measuring a distance of less than 10 mm.

15. The method according to claim 12, further comprising measuring received laser light using self-mixing interferometry, SMI.
